(19) United States
(12) Patent Application Publication
(10) Pub. No.: US 2024/0203692 A1
(43) Pub. Date: Jun. 20, 2024

(54) PLASMA PROCESSING APPARATUS AND PLASMA CONTROL METHOD

(71) Applicants: Tokyo Electron Limited, Tokyo (JP); The University of Shiga Prefecture, Shiga (JP)

(72) Inventors: Shin OOWADA, Tokyo (JP); Kazushi KANEKO, Yamanashi (JP); Masaaki MATSUKUMA, Yamanashi (JP); Eiki KAMATA, Yamanashi (JP); Satoru KAWAKAMI, Yamanashi (JP); Taro IKEDA, Yamanashi (JP); Osamu SAKAI, Shiga (JP)

(73) Assignees: Tokyo Electron Limited, Tokyo (JP); The University of Shiga Prefecture, Shiga (JP)

(21) Appl. No.: 18/590,058

(22) Filed: Feb. 28, 2024

Related U.S. Application Data
(63) Continuation of application No. PCT/JP2022/031485, filed on Aug. 22, 2022.

(30) Foreign Application Priority Data
Sep. 3, 2021 (JP) 2021-143717

(51) Int. Cl. H01J 37/32

(52) U.S. Cl. CPC H01J 37/32284; H01J 37/3222; H01J 37/32238; H01J 37/32256; H01J 37/32715; H01J 2237/327

(57) ABSTRACT

A plasma processing apparatus includes a processing container, an electromagnetic wave generator, and a resonator array structure. The processing container provides a processing space. The electromagnetic wave generator generates an electromagnetic wave for plasma excitation that is supplied to the processing space. The resonator array structure is formed by arranging resonators configured to resonate with a magnetic field component of the electromagnetic wave, each of the resonators having a size smaller than a wavelength of the electromagnetic wave, and is positioned in the processing container.

### CROSS-REFERENCE TO RELATED APPLICATIONS

This application is a bypass continuation application of international application No. PCT/JP2022/031485 having an international filing date of Aug. 22, 2022 and designating the United States, the international application being based upon and claiming the benefit of priority from Japanese Patent Application No. 2021-143717, filed on Sep. 3, 2021, the entire contents of each are incorporated herein by reference.

### TECHNICAL FIELD

The present disclosure relates to a plasma processing apparatus and a plasma control method.

### BACKGROUND

Patent Document 1 discloses a plasma processing apparatus that generates a plasma by supplying a microwave for plasma excitation into a processing container.
Patent Document 1: JP2009-245593A

The present disclosure provides a technique capable of realizing high density of a plasma in a wide range.

### SUMMARY

According to an aspect of an embodiment, a plasma processing apparatus includes a processing container that provides a processing space; an electromagnetic wave generator that generates an electromagnetic wave for plasma excitation that is supplied to the processing space; and a resonator array structure that is formed by arranging resonators configured to resonate with a magnetic field component of the electromagnetic wave, each of the resonators having a size smaller than a wavelength of the electromagnetic wave, and is positioned in the processing container.

### BRIEF DESCRIPTION OF DRAWINGS

FIG. 1 is a schematic cross-sectional view illustrating an example of a configuration of a plasma processing apparatus according to a first embodiment;

FIG. 2 is a plan view illustrating an example of a configuration of a dielectric window and a resonator array structure according to the first embodiment when viewed from below;

FIG. 3 is a view illustrating an example of a configuration of a first resonator according to the first embodiment;

FIG. 4 is a view illustrating an example of a configuration of a second resonator according to the first embodiment;

FIG. 5 is a view illustrating an example of a configuration of a third resonator according to the first embodiment;

FIG. 6 is a view illustrating another example of the configuration of the third resonator according to the first embodiment;

FIG. 7 is a view illustrating an example in which an insulating dielectric film is formed on each of resonators;

FIGS. 8A and 8B are views for illustrating an example of a relationship between a thickness of the dielectric film and an electric field strength around the resonator;

FIG. 9 is a view for illustrating another example of the relationship between the thickness of the dielectric film and the electric field strength around the resonator;

FIGS. 10A and 10B are views for illustrating an example of a relationship between the thickness of the dielectric film and a combined capacitance;

FIGS. 11A, 11B, and 11C are views for illustrating an example of a relationship between a thickness of a dielectric plate, a thickness of a coating film, and the combined capacitance;

FIG. 12 is a view illustrating an example of a disposition position of the resonator array structure;

FIG. 13 is a view illustrating another example of the disposition position of the resonator array structure;

FIGS. 14A and 14B are views for illustrating an example of a relationship between a separation distance between the resonator array structure embedded in the dielectric window and a lower surface of the dielectric window, and an electric field strength in a vicinity of the lower surface of the dielectric window;

FIG. 15 is a view illustrating an example of a relationship between S21 values of resonators and frequencies of microwaves;

FIG. 16 is a flowchart illustrating an example of a processing flow of plasma control processing according to the first embodiment;

FIG. 17 is a view for illustrating high density of a plasma in a wide range by the plasma control processing using the plasma processing apparatus according to the first embodiment;

FIG. 18 is a view illustrating an example of a timing chart of plasma control processing according to Modification 1 of the first embodiment;

FIG. 19 is a view illustrating an example of a timing chart of plasma control processing according to Modification 2 of the first embodiment;

FIG. 20 is a schematic cross-sectional view illustrating an example of an apparatus main body of a plasma processing apparatus according to a second embodiment;

FIG. 21 is a view illustrating an example of a timing chart of plasma control processing according to the second embodiment;

FIG. 22 is a flowchart illustrating an example of a processing flow of plasma control processing according to a third embodiment;

FIG. 23 is a view illustrating an example of a relationship between resonance frequencies of the resonators, a stacked number N of ring members, and the thickness of the dielectric plate; and

FIG. 24 is a view illustrating an example of a relationship between the resonance frequencies of the resonators, the stacked number N of the ring members, and an inner diameter of the ring member.

### DETAILED DESCRIPTION

Hereinafter, embodiments of a plasma processing apparatus and a plasma control method disclosed in the present application will be described in detail with reference to the drawings. The plasma processing apparatus and the plasma control method disclosed are not limited to the present embodiment. Further, the embodiments may be appropriately combined with each other within the scope that does not cause any inconsistency. In the respective drawings, similar or corresponding components will be denoted by the same reference numerals.

In a plasma processing apparatus using a microwave for plasma excitation, the power of the microwave supplied into the processing container may be increased in order to raise an electron density of a plasma. As the power of the microwave supplied into the processing container increases, the electron density of the plasma can be raised.

Here, it is known that when the electron density of the plasma reaches a certain upper limit value by increasing the power of the microwave supplied into the processing container, the dielectric constant of a space in the processing container becomes negative. The upper limit value of the electron density will be referred to as a “cutoff density” as appropriate. Further, as an indicator indicating whether the microwave propagates through the space, a refractive index is known. A refractive index N is represented by following Equation (1).

$$N = √ ε √ μ \qquad ( 1 )$$

ε: dielectric constant, μ: magnetic permeability

Since the magnetic permeability is generally positive, when the dielectric constant of the space in the processing container becomes negative, the refractive index of the space in the processing container becomes a pure imaginary number by Equation (1) above. As a result, the microwave is attenuated and cannot propagate through the space in the processing container. As described above, when the electron density of the plasma reaches the cutoff density, the microwave cannot propagate in the space in the processing container, and thus the power of the microwave is not sufficiently absorbed by the plasma. As a result, there is a problem that high density of a plasma generated in the processing container in a wide range is hindered.

Therefore, a technique capable of realizing high density of a plasma in a wide range is expected.

### First Embodiment

### Configuration of Plasma Processing Apparatus

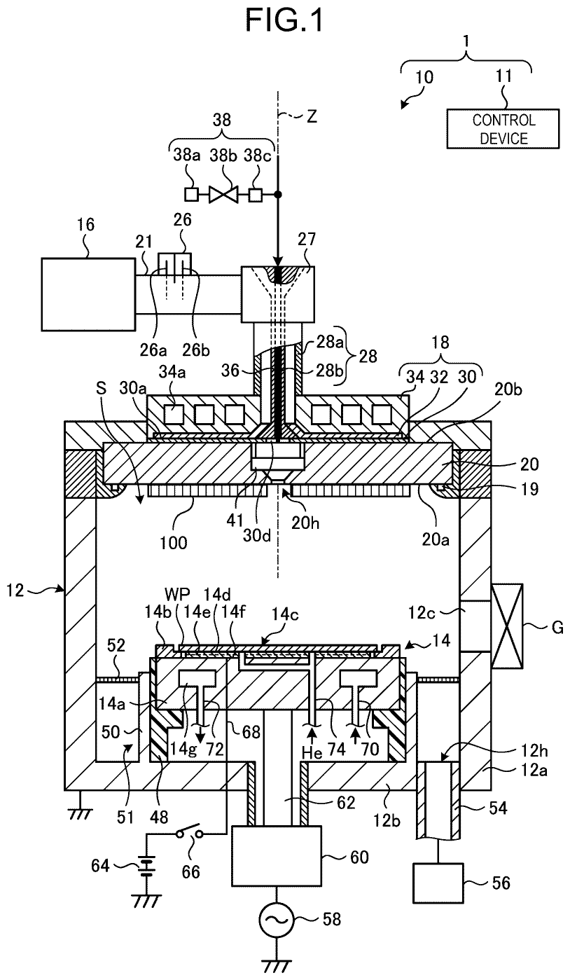

FIG. 1 is a schematic cross-sectional view illustrating an example of a configuration of a plasma processing apparatus 1 according to a first embodiment. The plasma processing apparatus 1 includes an apparatus main body 10 and a control device (an example of a controller) 11. The apparatus main body 10 includes a processing container 12, a stage 14, a microwave output device (an example of an electromagnetic wave generator) 16, an antenna 18, a dielectric window 20, and a resonator array structure 100.

The processing container 12 is, for example, formed in a substantially cylindrical shape with aluminum or the like whose surface is anodized, and provides a processing space S of a substantially cylindrical shape therein. The processing container 12 is grounded for a safety. Further, the processing container 12 has a side wall 12a and a bottom portion 12b. A central axis of the side wall 12a is defined as an axis Z. The bottom portion 12b is provided on a lower end side of the side wall 12a. An exhaust port 12h for exhaust is provided in the bottom portion 12b. Further, an upper end portion of the side wall 12a is opened. Further, an inner wall surface of the side wall 12a faces the processing space S. That is, the side wall 12a is provided such that an inner wall surface thereof faces the processing space S.

An opening 12c for loading/unloading a processing object WP is formed in the side wall 12a. The opening 12c is opened and closed by a gate valve G.

The dielectric window 20 is provided at the upper end portion of the side wall 12a, and closes an opening of the upper end portion of the side wall 12a from above. A lower surface (an example of the first surface) 20a of the dielectric window (an example of the dielectric) 20 faces the processing space S. That is, the dielectric window 20 is provided such that the lower surface 20a faces the processing space S. An O-ring 19 is disposed between the dielectric window 20 and the upper end portion of the side wall 12a.

The stage 14 is accommodated in the processing container 12. The stage 14 is provided to face the dielectric window 20 in the direction of the axis Z. The space between the stage 14 and the dielectric window 20 is the processing space S. The processing object WP is placed on the stage 14.

The stage 14 has a base 14a and an electrostatic chuck 14c. The base 14a is formed in a substantial disk shape with a conductive material such as aluminum. The base 14a is disposed in the processing container 12 such that the central axis of the base 14a substantially coincides with the axis Z.

The base 14a is supported by a tubular support 48 formed of an insulating material and extending in the axis Z direction. A conductive tubular support 50 is provided on the outer periphery of the tubular support 48. The tubular support 50 extends from the bottom portion 12b of the processing container 12 toward the dielectric window 20 along the outer periphery of the tubular support 48. An annular exhaust path 51 is formed between the tubular support 50 and the side wall 12a.

An annular baffle plate 52 in which through-holes are formed in a thickness direction is provided on an upper portion of the exhaust path 51. The exhaust port 12h described above is provided below the baffle plate 52. An exhaust device 56 having a vacuum pump such as a turbo molecular pump, an automatic pressure control valve, or the like is connected to the exhaust port 12h via an exhaust pipe 54. The exhaust device 56 can reduce the pressure in the processing space S to a desired vacuum level.

The base 14a functions as a radio-frequency electrode. A radio-frequency power supply 58 for RF bias is electrically connected to the base 14a via a power supply rod 62 and a matching unit 60. The radio-frequency power supply 58 supplies bias power at a predetermined frequency (for example, 13.56 MHz) suitable for controlling the energy of ions drawn into the processing object WP to the base 14a via the matching unit 60 and the power supply rod 62.

The matching unit 60 accommodates a matcher for matching between the impedance on the side of the radio-frequency power supply 58 and the impedance on the side of a load such as the electrode, the plasma, and the processing container 12. The matcher includes a blocking capacitor for generating self-bias.

The electrostatic chuck 14c is provided on an upper surface of the base 14a. The electrostatic chuck 14c attracts and holds the processing object WP by an electrostatic force. The electrostatic chuck 14c has a substantial disk-shaped outer shape, and has an electrode 14d, an insulating film (dielectric film) 14e, and an insulating film (dielectric film) 14f. The electrostatic chuck 14c is disposed on the upper surface of the base 14a such that the central axis of the electrostatic chuck 14c substantially coincides with the axis Z. The electrode 14d of the electrostatic chuck 14c is configured with a conductive film and is provided between the insulating film 14e and the insulating film 14f. A direct-current power supply 64 is electrically connected to the electrode 14d via a covered wire 68 and a switch 66. The electrostatic chuck 14c can attract and hold the processing object WP on the upper surface thereof by an electrostatic force generated by a direct-current voltage applied from the direct-current power supply 64. The upper surface of the electrostatic chuck 14c is a placement surface on which the processing object WP is to be placed, and faces the processing space S. That is, the electrostatic chuck 14c is provided such that the upper surface that is a placement surface faces the processing space S. Further, an edge ring 14b is provided on the base 14a. The edge ring 14b is disposed to surround the processing object WP and the electrostatic chuck 14c. The edge ring 14b may also be called a focus ring.

A flow path 14g is provided in the base 14a. A coolant is supplied from a chiller unit (not illustrated) to the flow path 14g via a pipe 70. The coolant supplied to the flow path 14g is returned to the chiller unit via a pipe 72. The temperature of the base 14a is controlled by the coolant whose temperature is controlled by the chiller unit circulating through the flow path 14g of the base 14a. By controlling the temperature of the base 14a, the temperature of the processing object WP on the electrostatic chuck 14c is controlled via the electrostatic chuck 14c on the base 14a.

Further, the pipe 74 for supplying a heat transfer gas such as a He gas between the upper surface of the electrostatic chuck 14c and a rear surface of the processing object WP is formed in the stage 14.

The microwave output device 16 outputs microwaves (an example of electromagnetic waves) for exciting the processing gas supplied into the processing container 12. The microwave output device 16 can adjust the frequency, a power, a bandwidth, or the like of the microwaves. The microwave output device 16 can generate microwaves of a single frequency by, for example, setting the bandwidth of the microwaves to be substantially zero (0). Further, the microwave output device 16 can generate a microwave that includes frequency components that belong to a predetermined frequency bandwidth (hereinafter, referred to as a “broadband microwave” as appropriate). The powers of the frequency components may be the same power, or only the central frequency component in the band may have a power larger than the powers of the other frequency components. The microwave output device 16 can adjust the power of the microwave within the range of 0 W to 5000 W, for example. The microwave output device 16 can adjust the frequency of the microwave or the central frequency of the broadband microwave within the range of, for example, 2.3 GHz to 2.5 GHZ, and can adjust the bandwidth of the broadband microwave in the range of, for example, 0 MHz to 100 MHz. Further, the microwave output device 16 can adjust the pitch (carrier pitch) of the frequencies of the frequency components of the broadband microwave within the range of, for example, 0 to 25 kHz.

Further, the apparatus main body 10 includes a waveguide 21, a tuner 26, a mode converter 27, and a coaxial waveguide 28. The output of the microwave output device 16 is connected to one end of the waveguide 21. The other end of the waveguide 21 is connected to the mode converter 27. The waveguide 21 is, for example, a rectangular waveguide. The waveguide 21 includes the tuner 26. The tuner 26 has a movable plate 26a and a movable plate 26b. By adjusting the amount of protrusion of each of the movable plate 26a and the movable plate 26b with respect to the interior space of the waveguide 21, the impedance of the microwave output device 16 and the impedance of the load can be matched.

The mode converter 27 converts the mode of the microwave outputted from the waveguide 21, and supplies the microwave after the mode conversion to the coaxial waveguide 28. The coaxial waveguide 28 includes an outer conductor 28a and an inner conductor 28b. The outer conductor 28a and the inner conductor 28b have a substantially cylindrical shape. The outer conductor 28a and the inner conductor 28b are disposed on an upper portion of the antenna 18 such that the central axes of the outer conductor 28a and the inner conductor 28b substantially coincide with the axis Z. The coaxial waveguide 28 transmits the microwave whose mode has been converted by the mode converter 27 to the antenna 18.

The antenna 18 supplies the microwave into the processing space S. The antenna 18 is an example of an electromagnetic wave supply. The antenna 18 is provided on an upper surface 20b of the dielectric window 20, and supplies the microwave to the processing space S via the dielectric window 20. The antenna 18 includes a slot plate 30, a dielectric plate 32, and a cooling jacket 34. The slot plate 30 is formed in a substantial disk shape with a conductive metal. The slot plate 30 is provided on the upper surface 20b of the dielectric window 20 such that the central axis of the slot plate 30 coincides with the axis Z. Slot holes 30a are formed in the slot plate 30. The slot holes 30a constitute, for example, slot pairs. Each of the slot pairs includes the two slot holes 30a having an elongated shape extending in directions intersecting each other. The slot pairs are arranged along one or more concentric circles around the central axis of the slot plate 30. Further, a through-hole 30d through which a conduit 36 to be described later can pass is formed in a central portion of the slot plate 30.

The dielectric plate 32 is formed in a substantial disk shape with a dielectric material such as quartz. The dielectric plate 32 is provided on the slot plate 30 such that the central axis of the dielectric plate 32 substantially coincides with the axis Z. The cooling jacket 34 is provided on the dielectric plate 32. The dielectric plate 32 is provided between the cooling jacket 34 and the slot plate 30.

The surface of the cooling jacket 34 is conductive. A flow path 34a is formed in the cooling jacket 34. A coolant is supplied from a chiller unit (not illustrated) to the flow path 34a. The lower end of the outer conductor 28a is electrically connected to an upper portion surface of the cooling jacket 34. Further, a lower end of the inner conductor 28b is electrically connected to the slot plate 30 through an opening formed in a central portion of the cooling jacket 34 and the dielectric plate 32.

The microwaves propagated through the coaxial waveguide 28 propagate through the dielectric plate 32 and are radiated from the slot holes 30a of the slot plate 30 into the processing space S via the dielectric window 20.

The resonator array structure 100 is formed by arranging resonators configured to resonate with a magnetic field component of the microwave and whose size is smaller than a wavelength of the microwave, and is positioned in the processing container 12.

When the resonator array structure 100 is positioned in the processing container 12, the microwave supplied to the processing space S by the antenna 18 and the resonators of the resonator array structure 100 can be caused to resonate. Due to the resonance between the microwave and the resonators, the microwave can be efficiently supplied into the processing space S of the processing container 12, and the magnetic permeability of the processing space S can be made negative. When the magnetic permeability of the processing space S is negative, although the electron density of the plasma generated in the processing space S reaches the cutoff density and the dielectric constant of the processing space S is negative, the refractive index becomes a real number by the above Equation (1), so that microwave can be propagated in the processing space S. As a result, although the electron density of the plasma generated in the processing space S reaches the cutoff density, the microwave can propagate to exceed a skin depth of the plasma, the power of the microwave is efficiently absorbed by the plasma, and as a result, high density of a plasma in a wide range beyond the skin depth of the plasma can be generated. That is, according to the plasma processing apparatus 1 of the present embodiment, the resonator array structure 100 is positioned in the processing container 12, so that high density of a plasma in a wide range can be realized.

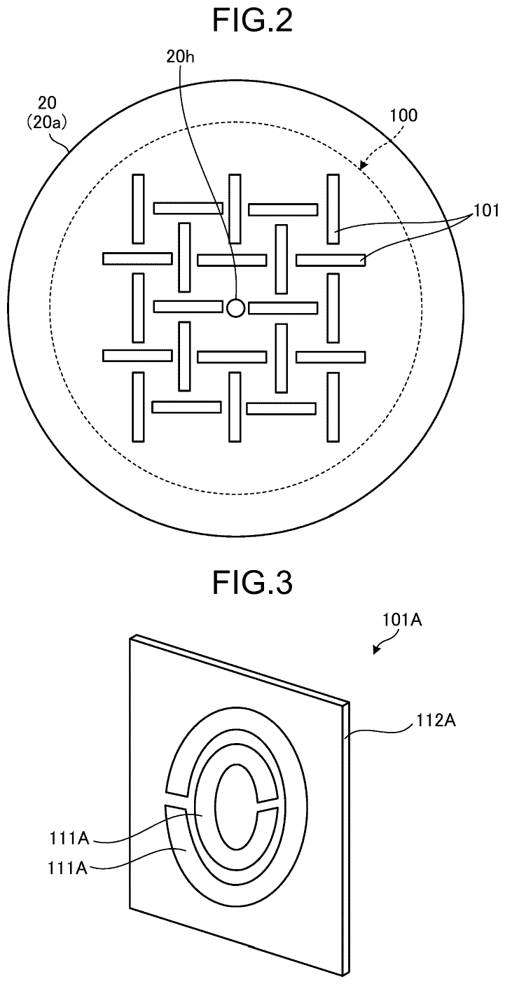

Hereinafter, a detailed configuration of the resonator array structure 100 will be described with reference to FIGS. 1 and 2. FIG. 2 is a plan view illustrating an example of a configuration of the dielectric window 20 and the resonator array structure 100 according to the first embodiment when viewed from below. FIG. 2 illustrates the lower surface 20a of the dielectric window 20 in a disk shape.

As illustrated in FIGS. 1 and 2, the resonator array structure 100 is disposed along the lower surface 20a of the dielectric window 20.

The resonator array structure 100 is formed by arranging resonators 101 in a lattice shape, which is configured to resonate with a magnetic field component of the microwave and whose size is smaller than a wavelength of the microwave. Specifically, the resonators 101 include at least one resonator of a first resonator 101A, a second resonator 101B, and a third resonator 101C illustrated in FIGS. 3 to 5. Each of the resonators 101 configures a series resonance circuit constituted with a capacitor equivalent element and a coil equivalent element. The series resonance circuit is realized by patterning a conductor on a plane.

FIG. 3 is a view illustrating an example of a configuration of the first resonator 101A according to a first embodiment. The first resonator 101A illustrated in FIG. 3 has a structure in which two C-shaped ring members 111A, which are made of a conductor, in opposite directions from each other, and concentric with each other, are stacked on one surface of a dielectric plate 112A. The capacitor equivalent elements are formed on opposing surfaces of the ring member 111A on the inner side and the ring member 111A on the outer side and at both end portions of each of the ring members 111A, and the coil equivalent element is formed along each of the ring members 111A. As a result, the first resonator 101A can configure a series resonance circuit.

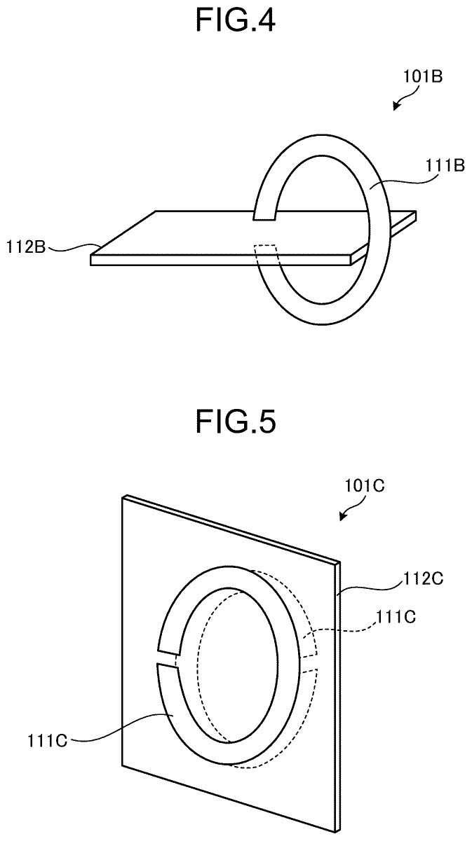

FIG. 4 is a view illustrating an example of a configuration of the second resonator 101B according to the first embodiment. The second resonator 101B illustrated in FIG. 4 has a structure in which a dielectric plate 112B is interposed between both ends of the C-shaped ring member 111B made of a conductor. The capacitor equivalent elements are formed at both end portions of the ring member 111B, and the coil equivalent element is formed along the ring member 111B. As a result, the second resonator 101B can configure a series resonance circuit. In the second resonator 101B illustrated in FIG. 4, another dielectric plate different from the dielectric plate 112B may be bonded on one surface of the ring member 111B.

FIG. 5 is a view illustrating an example of a configuration of the third resonator 101C according to the first embodiment. The third resonator 101C illustrated in FIG. 5 has a structure in which two C-shaped ring members 111C are made of a conductor and a dielectric plate 112C is disposed between the ring members 111C adjacently disposed in opposite directions from each other. That is, in the third resonator 101C, the dielectric plate 112C is interposed between the two C-shaped ring members 111C that are in opposite directions from each other. The capacitor equivalent elements are formed on opposing surfaces of the two C-shaped ring members 111C and at both end portions of each of the ring members 111C, and the coil equivalent element is formed along each of the ring members 111C. As a result, the third resonator 101C can configure a series resonance circuit.

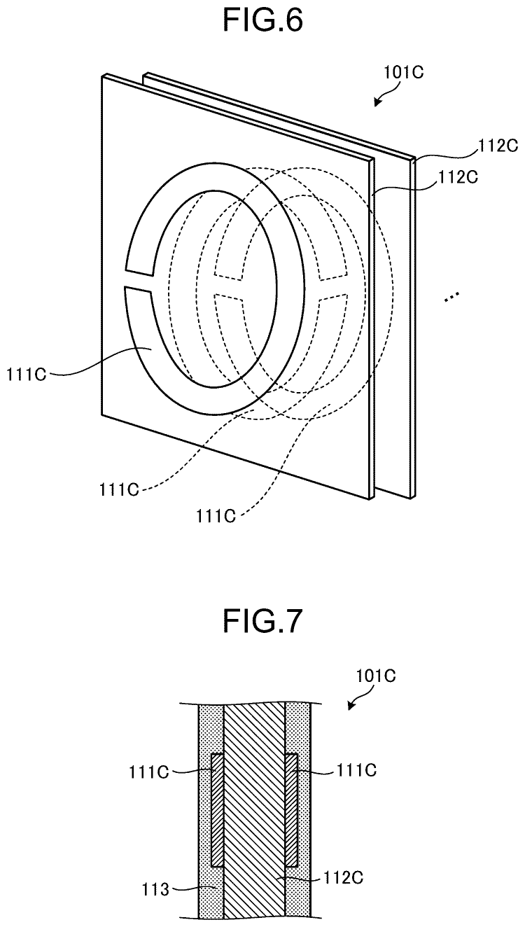

In the third resonator 101C illustrated in FIG. 5, the number of the ring members 111C disposed (hereinafter, also referred to as a “stacked number”) is 2, but the stacked number of the ring members 111C may be larger than 2. FIG. 6 is a view illustrating another example of the configuration of the third resonator 101C according to the first embodiment. The third resonator 101C illustrated in FIG. 6 has a structure in which the N (N≥2) C-shaped ring members 111C are made of a conductor and the dielectric plate 112C is disposed between the ring members 111C adjacently disposed in opposite directions from each other. With this structure as well, the third resonator 101C can configure a series resonance circuit.

Further, an insulating coating film may be formed on each of the resonators 101. FIG. 7 is a view illustrating an example in which an insulating dielectric film is formed on each of the resonators 101. FIG. 7 is a side cross-sectional view of the third resonator 101C illustrated in FIG. 5. An insulating coating film (an example of a dielectric film) 113 is formed on the surface of the third resonator 101C. The material of the coating film 113 is, for example, ceramic. The thickness of the coating film 113 is, for example, in the range of 0.001 mm to 2 mm. By forming the insulating coating film 113 on each of the resonators 101, an abnormal discharge can be suppressed in each of the resonators 101.

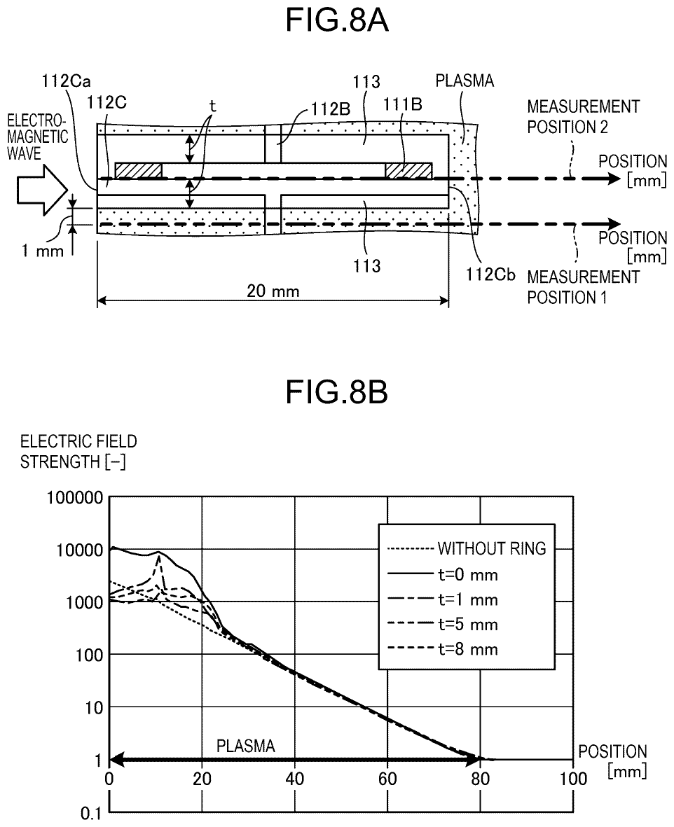

FIGS. 8A and 8B are views for illustrating an example of a relationship between a thickness of the dielectric film and an electric field strength around the resonator 101. As described above, in one embodiment, an insulating dielectric film may be formed on each of the resonators 101. The present inventors have supplied electromagnetic waves to the resonator 101 by changing the thickness of the dielectric film and have examined the electric field strength generated around the resonator 101 by simulation. FIG. 8A is a schematic diagram illustrating an example of a resonator used in a simulation. The resonator basically has the same structure as the second resonator 101B illustrated in FIG. 4. However, the other dielectric plate 112C having a width of 20 mm, which is different from the dielectric plate 112B, is bonded on one surface (lower surface) of the ring member 111B. Further, the dielectric plate 112C and the coating film 113 are formed as insulating dielectric films on both surfaces of the ring member 111B of the resonator in the thickness direction.

In the simulations using the resonator illustrated in FIG. 8A, electromagnetic waves are supplied from the side of one end 112Ca of the dielectric plate 112C along a plane direction of the dielectric plate 112C, in a state where a plasma having an electron density of 3×10¹¹/cm³ is generated around the resonator. In the simulation, a thickness t of the dielectric film is set to four types of 0 mm, 1 mm, 5 mm, and 8 mm, and the electric field strength generated at a measurement position (a measurement position 1 in FIG. 8A) spaced apart from one surface (lower surface) of the coating film 113 by 1 mm is measured. When the thickness t of the dielectric film is 0 mm, the resonator is configured by the ring member 111B having a thickness of 1 mm and the dielectric plate 112C having a thickness of 1 mm. When the thickness t of the dielectric film is 1 mm or more, the resonator is configured by bonding the coating film 113 having a thickness of t mm, which is the same material as the dielectric plate 112C, on the ring member 111B, and bonding the coating film 113 having a thickness of (t-1) mm below the dielectric plate 112C. For example, when the thickness t of the dielectric film is 1 mm, the resonator is configured by bonding the coating film 113 having a thickness of 1 mm on the ring member 111B. When the thickness t of the dielectric film is 5 mm, the resonator is configured by bonding the coating film 113 having a thickness of 5 mm on the ring member 111B and bonding the coating film 113 having a thickness of 4 mm below the dielectric plate 112C. When the thickness t of the dielectric film is 8 mm, the resonator is configured by bonding the coating film 113 having a thickness of 8 mm on the ring member 111B and bonding the coating film 113 having a thickness of 7 mm below the dielectric plate 112C. That is, the thickness of the dielectric film on the upper and lower surfaces of the ring member 111B is the thickness that includes the dielectric plate 112C and the coating film 113.

FIG. 8B illustrates the distribution of the electric field strength according to the position along the measurement position 1, with the one end 112Ca of the dielectric plate 112C set to 0 mm for each the thickness t of the dielectric film. The electric field strength is normalized with reference to the electric field strength at the end position of the plasma on the side of the other end 112Cb of the dielectric plate 112C. FIG. 8B also illustrates, as a reference example, the distribution of the electric field strength in a case where the ring member 111B is not provided.

As illustrated in FIG. 8B, regardless of the thickness t of the dielectric film, the electric field strength is substantially larger than the electric field strength when the ring member 111B is not provided, in the range in the vicinity of the resonator in which the position of the dielectric plate 112C with respect to the one end 112Ca is 20 mm or less. In this way, the simulation results illustrated in FIG. 8B illustrate that electric field coupling can be generated between the ring member 111B of the resonator and the plasma around the resonator although the thickness t of the dielectric film is changed. That is, from the simulation results, it can be understood that, when the ring member 111B is present, the electric field strength of the electromagnetic wave in the plasma that is parallel to the ring member 111B increases as the thickness t of the dielectric film is thinner as compared with the case where the ring member 111B is not provided and it is easy to affect the plasma.

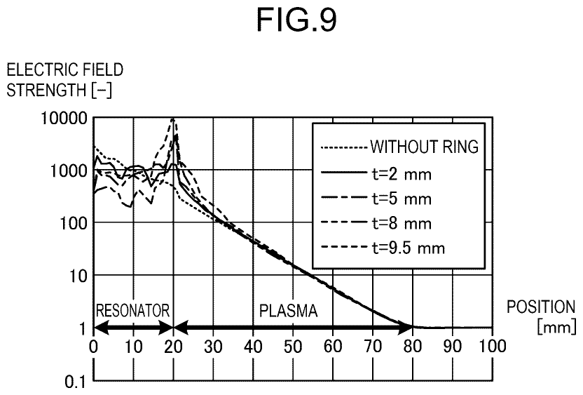

FIG. 9 is a view for illustrating another example of the relationship between the thickness of the dielectric film and the electric field strength around the resonator 101. The present inventors have supplied electromagnetic waves to the resonator 101 by changing the thickness of the dielectric film and have examined the electric field strength generated around the resonator 101 by simulation. The resonator used in the simulation is the same as the resonator illustrated in FIG. 8A. Further, in the simulation, the thickness t of the dielectric film is set to four types of 2 mm, 5 mm, 8 mm, and 9.5 mm, and the electric field strength generated in the same plane as one surface (lower surface) of the ring member 111B is measured. That is, at a measurement position 2 in FIG. 8A, the electric field strength is measured with the left side of the one end 112Ca of the dielectric plate 112C set to 0. When the thickness t of the dielectric film is 0 mm, the resonator is configured by the ring member 111B having a thickness of 1 mm and the dielectric plate 112C having a thickness of 1 mm. When the thickness t of the dielectric film is 2 mm or more, the resonator is configured by bonding the coating film 113 having a thickness of t mm, which is the same material as the dielectric plate 112C, on the ring member 111B, and bonding the coating film 113 having a thickness of (t−1) mm below the dielectric plate 112C. For example, when the thickness t of the dielectric film is 2 mm, the resonator is configured by bonding the coating film 113 having a thickness of 2 mm on the ring member 111B and bonding the coating film 113 having a thickness of 1 mm below the dielectric plate 112C. When the thickness t of the dielectric film is 5 mm, the resonator is configured by bonding the coating film 113 having a thickness of 5 mm on the ring member 111B and bonding the coating film 113 having a thickness of 4 mm below the dielectric plate 112C. When the thickness t of the dielectric film is 8 mm, the resonator is configured by bonding the coating film 113 having a thickness of 8 mm on the ring member 111B and bonding the coating film 113 having a thickness of 7 mm below the dielectric plate 112C. When the thickness t of the dielectric film is 9.5 mm, the resonator is configured by bonding the coating film 113 having a thickness of 9.5 mm on the ring member 111B and bonding the coating film 113 having a thickness of 8.5 mm below the dielectric plate 112C. That is, the thickness of the dielectric film on the upper and lower surfaces of the ring member 111B is the thickness that includes the dielectric plate 112C and the coating film 113.

FIG. 9 illustrates the distribution of the electric field strength according to the position along the measurement position 2, with the one end 112Ca of the dielectric plate 112C set to 0 mm for each of the thickness t of the dielectric film. The electric field strength is normalized with reference to the electric field strength at the end position of the plasma on the side of the other end 112Cb of the dielectric plate 112C. FIG. 9 also illustrates, as a reference example, the distribution of the electric field strength in a case where the ring member 111B is not provided.

As illustrated in FIG. 9, when the thickness t of the dielectric film is 5 mm or more, the electric field strength increases at the other end 112Cb of the dielectric plate 112C at which the position of the dielectric plate 112C with respect to the one end 112Ca is 20 mm. As described above, from the simulation result of FIG. 9, it can be understood that, when the thickness t of the dielectric film is 5 mm or more, electric field coupling can be generated between the ring member 111B of the resonator and the plasma on the side of the other end 112Cb of the dielectric plate 112C. That is, from the simulation result, it can be understood that, when the thickness of the dielectric film is 5 mm or more, the electric field strength of the boundary surface between the ring member 111B and the plasma is higher than the electric field strength penetrating the ring member 111B and it is easy to affect the plasma.

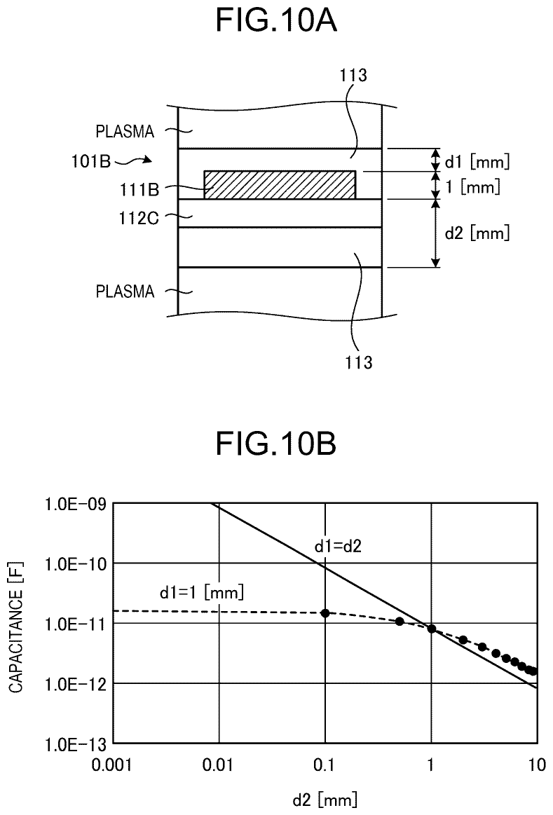

Further, it is preferable that the thickness of the dielectric film be substantially the same on both surfaces of the ring member 111B of the resonator in the thickness direction. FIGS. 10A and 10B are views for illustrating an example of a relationship between the thickness of the dielectric film and a combined capacitance. The dielectric film is configured with the dielectric plate 112C and the coating film 113. The present inventors have studied the variation of the combined capacitance while changing the thickness of the coating film 113 on both surfaces of the ring member 111B of the resonator in the thickness direction. FIG. 10A is a schematic diagram illustrating an example of a resonator used in the study. The resonator used in the study basically has the same structure as the second resonator 101B illustrated in FIG. 4. However, the other dielectric plate 112C different from the dielectric plate 112B is bonded on one surface (lower surface) of the ring member 111B. Further, the insulating coating films 113 are formed on both surfaces (the upper surface and the lower surface) of the ring member 111B of the resonator in the thickness direction. The thickness of the dielectric film is d1 [mm] (the thickness of the coating film 113) on the upper surface side of the ring member 111B, and is d2 [mm] (the thickness of the dielectric plate 112C+the thickness of the coating film 113) on the lower surface side.

FIG. 10B is a graph in which each of the capacitance of the dielectric film when d1=d2 and the capacitance of the dielectric film when d=1 [mm] and d2=variable is plotted in association with the magnitude of d2. In FIG. 10B, assuming that the plasma is metal, the vertical axis represents the capacitance (i.e., the capacitance of the dielectric film) obtained by combining the capacitance of the portion of the coating film 113 positioned on the upper surface side of the ring member 111B, the capacitance of the dielectric plate 112C, and the capacitance of the portion of the coating film 113 positioned on the lower surface side of the ring member 111B.

As illustrated in FIG. 10B, when d1=d2, the combined capacitance changes linearly. That is, it can be understood that, when d1=d2, uniform capacitance can be obtained on both surfaces of the ring member 111B of the resonator in the thickness direction and thus the concentration difference of the plasma density around the resonator can be suppressed. Meanwhile, when d1=1 [mm] and d2=variable, the combined capacitance does not vary significantly as d2 decreases. In other words, the combined capacitance largely depends on the capacitance of the portion of the dielectric film having the largest thickness. The present inventors conducted further studies based on the study results. As a result, it has been found that, when d2/d1 falls within the range of 0.8 to 1.2, the deviation of the capacitance on both surfaces of the ring member 111B of the resonator in the thickness direction falls within 5% or less and thus, the concentration difference of the plasma density around the resonator can be suppressed. Therefore, it is preferable that the thickness of the dielectric film be substantially the same on both surfaces of the ring member 111B of the resonator in the thickness direction.

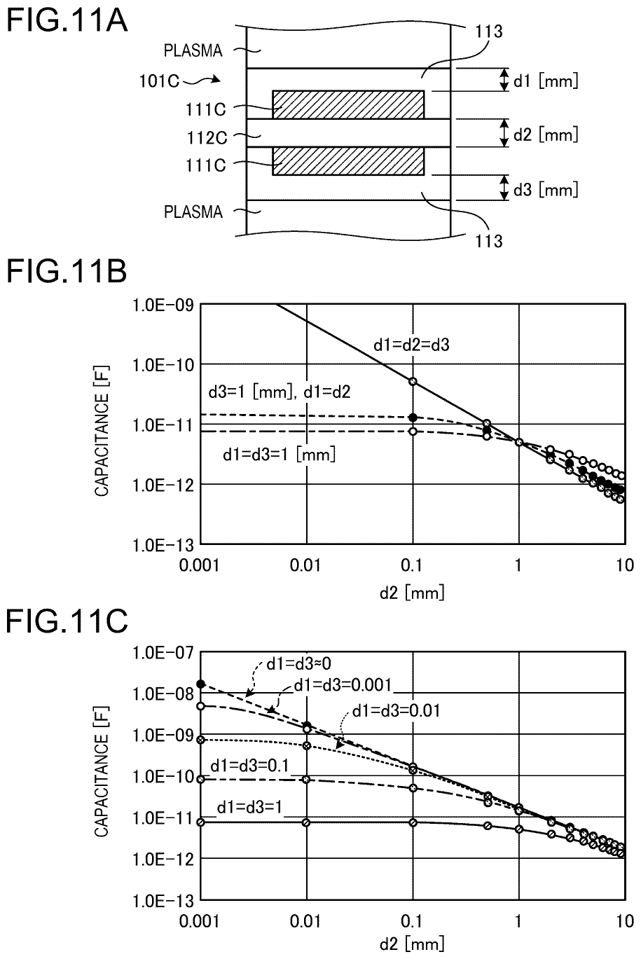

In the examples of FIGS. 10A and 10B, the relationship between the thickness of the coating film 113 and the combined capacitance is examined using a resonator having the same structure as that of the second resonator 101B illustrated in FIG. 4, but the same examination can also be performed in a case where the resonator is the third resonator 101C illustrated in FIG. 5. FIGS. 11A, 11B, and 11C are views for illustrating an example of the relationship between the thickness of the dielectric plate 112C, the thickness of the coating film 113, and the combined capacitance. The present inventors have studied the variation of the combined capacitance while varying the thickness of the coating film 113 that covers the two ring members 111C that interposes the dielectric plate 112C of the resonator and the thickness of the dielectric plate 112C. FIG. 11A is a schematic diagram illustrating an example of a resonator used in the study. The resonator used in the study basically has the same structure as the third resonator 101C illustrated in FIG. 5. However, the two ring members 111C that interpose the dielectric plate 112C of the resonator are each covered with the insulating coating film 113. The thickness of the coating film 113 that covers the ring member 111C on the upper side is d1 [mm], the thickness of the dielectric plate 112C is d2 [mm], and the thickness of the coating film 113 that covers the ring member 111C on the lower side is d3 [mm].

FIG. 11B is a graph in which each of the combined capacitance of the third resonator 101C when d1=d2=d3, the combined capacitance of the third resonator 101C when d3=1 [mm] and d1=d2, and the combined capacitance of the third resonator 101C when d1=d3=1 [mm] and d2=variable is plotted in association with the magnitude of d2. In FIG. 11B, assuming that the plasma is metal, the vertical axis is the capacitance obtained by combining the capacitance of the coating film 113 that covers the ring member 111C on the upper side, the capacitance of the dielectric plate 112C, and the capacitance of the coating film 113 that covers the ring member 111C on the lower side.

As illustrated in FIG. 11B, when d1=d2=d3, the combined capacitance changes linearly. In other words, it can be understood that, when d1=d2=d3, uniform capacitance can be obtained on both the surface of the ring member 111C on the upper side and the surface of the ring member 111C on the lower side and thus the concentration difference of the plasma density around the resonator can be suppressed. Meanwhile, when d3=1 [mm] and d1=d2, the combined capacitance does not vary significantly as d2 decreases. Similarly, when d1=d3=1 [mm] and d2=variable, the combined capacitance does not vary as d2 decreases. In other words, the combined capacitance largely depends on the capacitance of the portion of the dielectric film having the largest thickness. The present inventors conducted further studies based on the study results. As a result, it has been found that, when d2/d1 and d2/d3 are in the range of 0.8 to 1.2, the deviation in capacitance between the surface of the ring member 111C on the upper side of the resonator and the surface of the ring member 111C on the lower side falls within 5% and thus the concentration difference of the plasma density around the resonator can be suppressed. Therefore, it is preferable that the thickness of the coating film 113 be substantially the same on the surface of the ring member 111C on the upper side of the resonator and the surface of the ring member 111C on the lower side, and be substantially the same as the thickness of the dielectric plate 112C.

FIG. 10A illustrates a structure in which the ring member 111B has one layer and the dielectric film has two layers, FIG. 11A illustrates a structure in which the ring member 111C has two layers and the dielectric film has three layers, but the ratio of the thickness of the dielectric film may be set to be in the range of 0.8 to 1.2 even when the ring member 111C has three layers and the dielectric film has four layers. Similarly, even when the ring member 111C has n layers and the dielectric film has (n+1) layers, the ratio of the thickness of the dielectric film may be set to be in the range of 0.8 to 1.2.

Further, FIG. 11C illustrates the combined capacitance when the thickness d1=d3 of the coating film 113 is changed with respect to the thickness d2 of the dielectric plate 112C. When d1=d3 is approximately equal to 0 mm with respect to the thickness d2 of the dielectric plate 112C, a case where there is no coating film is illustrated. At this time, the resonator is configured with the ring member 111C and the dielectric plate 112C. At this time, when the thicknesses d1 and d3 of the coating film 113 are set to be 1/10 or less with respect to the thickness d2 of the dielectric plate 112C, the influence of the coating film 113 on the combined capacitance is substantially eliminated. That is, when a capacitance is designed using the thickness of the dielectric plate 112C, the ratio of the thickness of the dielectric plate 112C may be set to be in the range of 0.8 to 1.2, and the thickness of the coating film 113 may be set to be 1/10 or less with respect to the thickness of the dielectric plate 112C.

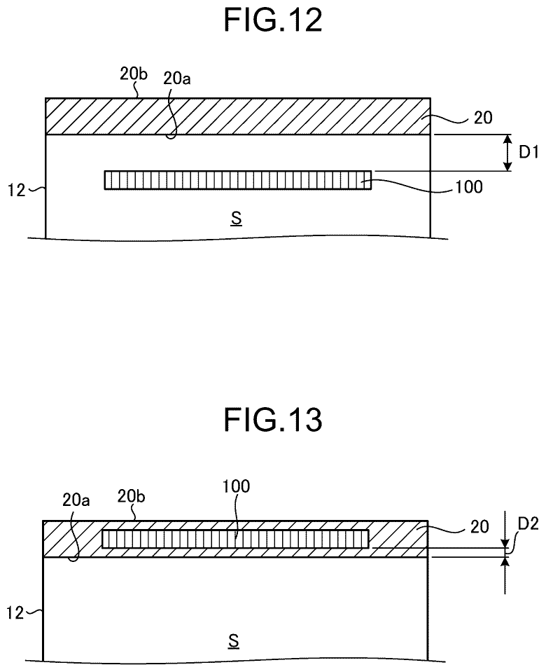

Further, the resonator array structure 100 illustrated in FIGS. 1 and 2 is disposed along the lower surface 20a of the dielectric window 20, but the disposition position of the resonator array structure 100 is not limited thereto. FIG. 12 is a view illustrating an example of a disposition position of the resonator array structure 100. As illustrated in FIG. 12, the resonator array structure 100 may be disposed to be spaced apart from the lower surface 20a of the dielectric window 20. In this case, it is preferable that a separation distance D1 between the resonator array structure 100 and the lower surface 20a of the dielectric window 20 be smaller than the skin depth of the plasma at the lower surface 20a. The separation distance D1 between the resonator array structure 100 and the lower surface 20a of the dielectric window 20 varies between the time when the plasma is present and the time when the plasma is not present. For example, it is assumed that a surface wave plasma (electron density of 3×10¹¹/cm³) is generated at the lower surface 20a of the dielectric window 20 by a radial line slot antenna at a frequency of 2.45 GHz. In this case, since the skin depth of the plasma is about 20 mm, the microwave can be propagated in the plasma. That is, when the separation distance D1 is 20 mm or less, the resonator array structure 100 responds to the propagating microwave. Meanwhile, as long as there is no plasma at the lower surface 20a of the dielectric window 20 and the microwave can propagate to the resonator array structure 100, the separation distance D1 is not limited.

FIG. 13 is a view illustrating another example of a disposition position of the resonator array structure 100. As illustrated in FIG. 13, the resonator array structure 100 may be embedded in the dielectric window 20. Specifically, the resonator array structure 100 may be spaced apart from the lower surface 20a of the dielectric window 20 and be embedded in the dielectric window 20. A separation distance D2 between the resonator array structure 100 and the lower surface 20a of the dielectric window 20 is preferably 2/4 or less when the wavelength of the electromagnetic wave (microwave) propagating through the dielectric window 20 is A.

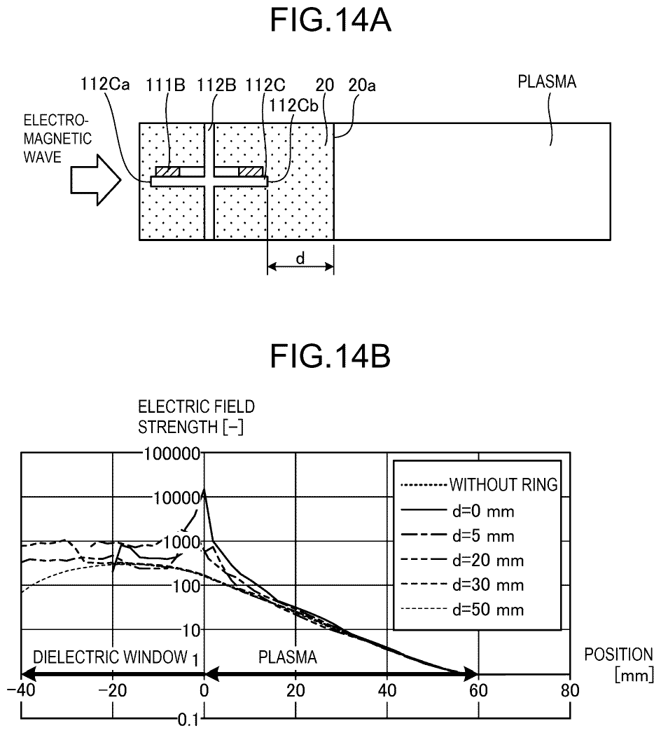

FIGS. 14A and 14B are views for illustrating an example of a relationship between the separation distance d between the resonator array structure 100 embedded in the dielectric window 20 and the lower surface 20a of the dielectric window 20, and the electric field strength in the vicinity of the lower surface 20a of the dielectric window 20. As described above, in one embodiment, the resonator array structure 100 may be spaced apart from the lower surface 20a of the dielectric window 20 and be embedded in the dielectric window 20. The present inventors have supplied the electromagnetic wave to the resonator 101 while changing the separation distance d between the resonator array structure 100 and the lower surface 20a of the dielectric window 20, and have examined the electric field strength generated in the vicinity of the lower surface 20a of the dielectric window 20 by simulation. FIG. 14A is a schematic diagram illustrating an example of the resonator (i.e., the one resonator 101 included in the resonator array structure 100) used in the simulation. The resonator basically has the same structure as the second resonator 101B illustrated in FIG. 4. However, the other dielectric plate 112C having a width of 20 mm, which is different from the dielectric plate 112B, is bonded on one surface (lower surface) of the ring member 111B.

In the simulation using the resonator illustrated in FIG. 14A, the electromagnetic wave is supplied from the one end 112Ca of the dielectric plate 112C along the plane direction of the dielectric plate 112C in a state where the resonator is spaced apart from the lower surface 20a of the dielectric window 20 and is embedded in the dielectric window 20. The lower surface 20a of the dielectric window 20 faces the plasma having an electron density of 3×10¹¹/cm³. Further, the material of the dielectric window 20 is polytetrafluoroethylene (PTFE), and the dielectric plate 112B and the dielectric plate 112C are also made of the same materials as the dielectric window 20. In this simulation, the separation distance d between the resonator and the lower surface 20a of the dielectric window 20 is set to five different values of 0 mm, 5 mm, 20 mm, 30 mm, and 50 mm, and the electric field strength in the vicinity of the lower surface 20a of the dielectric window 20 is measured.

FIG. 14B illustrates the distribution of the electric field strength according to the position with respect to the lower surface 20a of the dielectric window 20 along the surface direction of the dielectric plate 112C for each the separation distance d. The electric field strength is normalized with reference to the electric field strength at the end position of the plasma on the side of the other end 112Cb of the dielectric plate 112C. FIG. 14B also illustrates, as a reference example, the distribution of the electric field strength in a case where the ring member 111B is not provided.

As illustrated in FIG. 14B, when the separation distance d is 20 mm or less, the electric field strength at the lower surface 20a of the dielectric window 20 is larger than the electric field strength in a case where the ring member 111B is not provided. The wavelength 2 of the electromagnetic wave propagating through the dielectric window 20 made of PTFE is 106 mm. Therefore, it can be understood that electric field coupling can be generated between the ring member 111B of the resonator and the plasma when the separation distance d is λ/4 or less. That is, from the simulation results, it can be inferred that the power of the electromagnetic wave is sufficiently injected into the plasma when the separation distance d is λ/4 or less. Therefore, the separation distance D2 (see FIG. 13) between the resonator array structure 100 and the lower surface 20a of the dielectric window 20 is preferably 2/4 or less when the wavelength of the electromagnetic wave (microwave) propagating through the dielectric window 20 is 2.

Reference will again be made to FIG. 1. The conduit 36 is provided inside the inner conductor 28b of the coaxial waveguide 28. The through-hole 30d through which the conduit 36 can pass is formed in the central portion of the slot plate 30. The conduit 36 extends through the inside of the inner conductor 28b and is connected to the gas supply 38.

The gas supply 38 supplies a processing gas for processing the processing object WP to the conduit 36. The gas supply 38 includes a gas supply source 38a, a valve 38b, and a flow rate controller 38c. The gas supply source 38a is a supply source of a processing gas. The valve 38b controls the supply and the supply stop of a processing gas from the gas supply source 38a. The flow rate controller 38c is, for example, a mass flow controller or the like, and controls the flow rate of the processing gas from the gas supply source 38a.

Further, the apparatus main body 10 includes an injector 41. The injector 41 supplies gas from the conduit 36 to a through-hole 20h formed in the dielectric window 20. The gas supplied to the through-hole 20h of the dielectric window 20 is injected into the processing space S and excited by the microwave supplied from the antenna 18 to the processing space S via the dielectric window 20. As a result, the processing gas is turned into the plasma in the processing space S, and the processing object WP is processed by ions, radicals, or the like contained in the plasma.

The control device 11 includes a processor, a memory and an input/output interface. The memory stores a program, a process recipe, or the like. The processor reads a program from the memory and executes the program to collectively control each portion of the apparatus main body 10 via the input/output interface based on a process recipe stored in the memory.

For example, when a plasma is generated in the processing space S, the control device 11 controls such that the microwave supplied to the processing space S by the antenna 18 and the resonators 101 resonate in the target frequency band higher than the resonance frequencies of the resonators 101. Here, the resonance frequency is, for example, a frequency at which the transmissive characteristic values (for example, the S21 values) of the resonators 101 have a local minimum value.

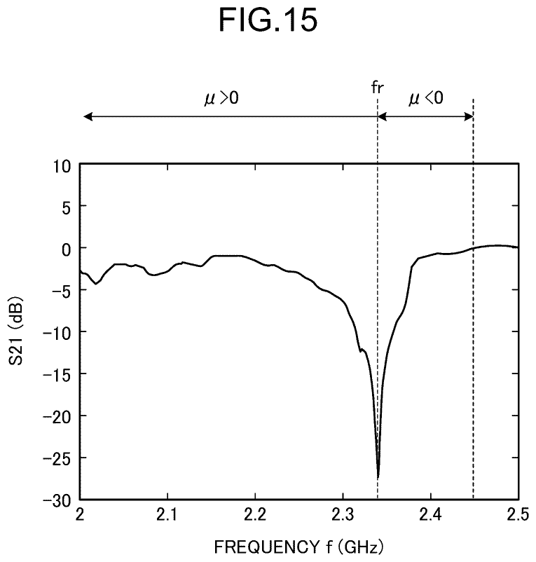

FIG. 15 is a view illustrating an example of a relationship between the S21 values of the resonators 101 and the frequencies of the microwave. When the frequency of the microwave supplied to the processing space S by the antenna 18 coincides with a resonance frequency fᵣ (=about 2.35 GHz) of the resonators 101, the S21 value of the resonators 101 becomes a local minimum value, and resonance between the microwave and the resonators 101 occurs. The resonance between the microwave and the resonators 101 is maintained even in a predetermined frequency band (for example, about 0.1 GHZ) higher than the resonance frequency fᵣ of the resonators 101. In a predetermined frequency band higher than the resonance frequency fᵣ of the resonators 101, both the dielectric constant and the magnetic permeability of the processing space S can be made negative by the resonance between the microwave and the resonators 101, and as can be understood from Equation (1) above, the microwave can be propagated in the processing space S. The target frequency band of the present embodiment is set to a predetermined frequency band (for example, about 0.1 GHZ) higher than the resonance frequency fᵣ of the resonators 101. The target frequency band is preferably, for example, 0.05 times or less the resonance frequency fᵣ of the resonators 101.

With respect to the propagation of the electromagnetic waves to the resonators, the relationship between the resonance frequency, the refractive index, the dielectric constant, and the magnetic permeability has been reported, for example, in [Electromagnetic parameter retrieval from inhomogeneous metamaterials] in [PHYSICAL REVIEW E 71, 036617 (2005)] by D. R. Smith, D. C. Vier, Th. Koschny and C. M. Soukoulis et al.

In this way, by causing the microwave and the resonators 101 to resonate in the target frequency band higher than the resonance frequency fᵣ of the resonators 101, even when the electron density of the plasma reaches the cutoff density, the microwave can propagate beyond the skin depth of the plasma, and the power of the microwave can be efficiently absorbed in the plasma. As a result, high density of a plasma in a wide range beyond the skin depth of the plasma can be generated. That is, according to the plasma processing apparatus 1 of the present embodiment, by causing the microwave and the resonators 101 to resonate in the target frequency band higher than the resonance frequency fᵣ of the resonators 101, high density of a plasma in a wide range can be achieved.

### Plasma Control Processing

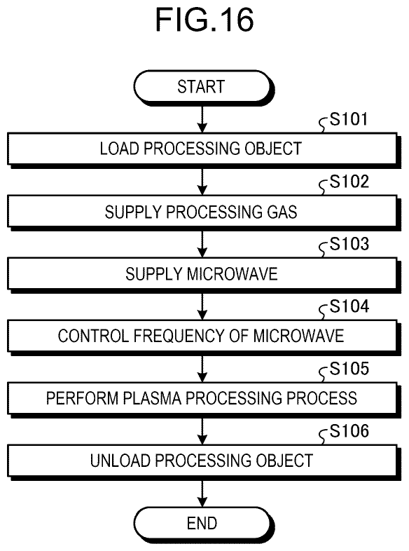

Next, an example of plasma control processing using the plasma processing apparatus 1 according to the first embodiment will be described. FIG. 16 is a flowchart illustrating an example of a processing flow of plasma control processing according to the first embodiment. The plasma control processing illustrated in FIG. 16 is realized by controlling each portion of the apparatus main body 10 by the control device 11.

First, the processing object WP is loaded into the processing container 12 and placed on the electrostatic chuck 14c (step S101). Then, the control device 11 opens the valve 38b, and controls the flow rate controller 38c such that the processing gas of a predetermined flow rate is supplied into the processing container 12 (step S102). The control device 11 controls the exhaust device 56 to adjust the pressure in the processing container 12.

Next, the control device 11 controls the microwave output device 16 to supply the microwave from the antenna 18 to the processing space S in the processing container 12 (step S103). As a result, the plasma of the processing gas is generated in the processing container 12. At this time, the electron density of the plasma reaches the cutoff density. When the electron density of the plasma reaches the cutoff density, the microwave cannot propagate in the processing space S in the processing container 12.

Therefore, the control device 11 controls the microwave output device 16 to control the frequency of the microwave, which is supplied from the antenna 18 to the processing space S in the processing container 12, to a frequency that belongs to the target frequency band (step S104). As a result, by generating the resonance between the microwave and the resonators 101, both the dielectric constant and the magnetic permeability of the plasma in the processing space S can be made negative, and as can be understood from Equation (1) above, the microwave can be propagated in the processing space S. As a result, in the processing space S in the processing container 12, the microwaves can propagate beyond the skin depth of the plasma, the power of the microwave is efficiently injected into the plasma, and as a result, high density of a plasma is generated in a wide range beyond the skin depth of the plasma.

Then, a plasma processing process is performed on the processing object WP by the plasma generated in the processing space S in the processing container 12 (step S105).

When the plasma processing process is completed, the processed processing object WP is unloaded from the processing container 12 by a robot arm (not illustrated) (step S106).

In the step S103 illustrated in FIG. 16, the control device 11 may control the microwave output device 16 to supply the microwave (broadband microwave) containing frequency components that belong to a predetermined frequency bandwidth from the antenna 18 to the processing space S in the processing container 12. In this case, the control device 11 may perform the following processing in the step S104. That is, the control device 11 may control the microwave output device 16 to control the frequency of the frequency components, which are included in the broadband microwave supplied from the antenna 18 to the processing space S in the processing container 12, to the target frequency band.

### High Density of Plasma in Wide Range

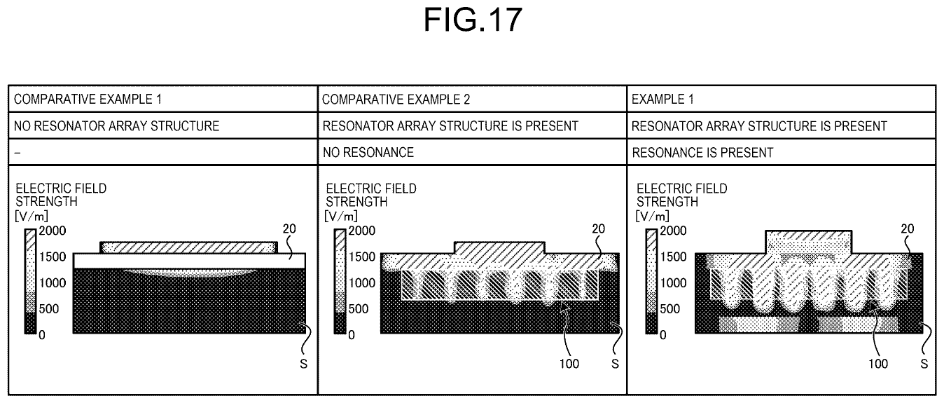

FIG. 17 is a view for illustrating high density of a plasma in a wide range by the plasma control processing using the plasma processing apparatus 1 according to the first embodiment. FIG. 17 illustrates the simulation results of the electric field strength in the vicinity of the dielectric window 20 when a plasma having an electron density of 3×10¹²/cm³ is generated in the processing space S in the processing container 12 and the microwave is supplied to the processing space S via the dielectric window 20.

Comparative Example 1 of FIG. 17 illustrates the result of supplying the microwave into the processing space S without disposing the resonator array structure 100 on the lower surface 20a of the dielectric window 20. In Comparative Example 1, the electric field strength is maximized at the surface of the dielectric window in the processing space S, and the microwave does not propagate to a wide space, so that the power of the microwave is not sufficiently injected into the plasma as space.

Comparative example 2 of FIG. 17 illustrates the result of supplying the microwave that does not resonate with the resonators 101, i.e., the microwave whose frequencies do not belong to the target frequency band, into the processing space S in a state where the resonator array structure 100 is disposed on the lower surface 20a of the dielectric window 20. In Comparative Example 2, compared with Comparative Example 1, since the electric field strength increases on the surface of the resonator array structure 100, the propagation distance of the microwave slightly increases, but the power of the microwave is not sufficiently injected into the plasma as space.

Example 1 of FIG. 17 illustrates the results obtained by supplying the microwave, which resonates with the resonators 101, i.e., the microwave whose frequencies belong to the target frequency band, into the processing space S by using the plasma processing apparatus 1 of the present embodiment. In Example 1, compared with Comparative Example 2, the electric field strength increases in a wide range of the surface of the resonator array structure 100, the microwave can propagate widely in space into the processing space S, and the power of the microwave absorbed in the plasma as space greatly increases.

When the microwave whose frequencies do not belong to the target frequency band is supplied to the processing space S, the dielectric constant of the processing space S is negative, the magnetic permeability remains positive, the propagation of the microwaves cannot propagate beyond the skin depth of the plasma, and the power of the microwave is not efficiently absorbed by the plasma. Therefore, high density of a plasma in a wide range is hindered. In contrast, in the plasma control processing using the plasma processing apparatus 1 of the present embodiment, the dielectric constant and the magnetic permeability in the processing space S can both be made negative by the resonance between the microwave and the resonators 101, and the microwave in the processing space S can propagate beyond the skin depth of the plasma. As a result, in the processing space S in the processing container 12, since the plasma is present in a wide range beyond the skin depth, the power of the microwave is efficiently absorbed by the plasma, and as a result high density of a plasma in a wide range beyond the skin depth of the plasma can be generated.

### Modification 1 of Plasma Control Processing

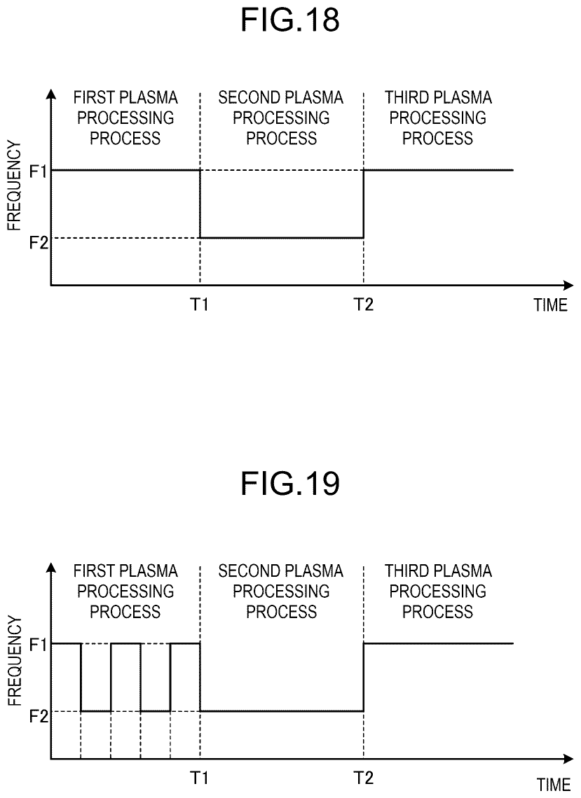

FIG. 18 is a view illustrating an example of a timing chart of plasma control processing according to Modification 1 of the first embodiment. In the first embodiment, when a plasma is generated in the processing space S, by controlling the frequency of the microwave to a frequency that belongs to the target frequency band, the propagation of the microwave is present in a wide range beyond the skin depth of the plasma, so that the power of the microwave is efficiently absorbed by the plasma, and as a result, high density of a plasma in a wide range beyond the skin depth of the plasma is realized. In Modification 1, the control device 11 controls the microwave output device 16 to switch the frequency of the microwave between a first frequency that belongs to the target frequency band and a second frequency that does not belong to the target frequency band, according to the timing for switching the plasma processing process successively performed by the plasma processing apparatus 1. For example, the plasma processing apparatus 1 successively executes a first plasma processing process, a second plasma processing process, and a third plasma processing process.

First, in the period in which the first plasma processing process is performed, the control device 11 sets the frequency of the microwave, which is supplied from the antenna 18 to the processing space S in the processing container 12, to a first frequency F1 that belongs to the target frequency band. As a result, in the period in which the first plasma processing process is performed, the dielectric constant and the magnetic permeability in the processing space S can both be made negative by the resonance between the microwave and the resonators 101, and the microwave can be propagated in the processing space S. As a result, in the processing space S in the processing container 12, since the plasma is present in a wide range beyond the skin depth, the power of the microwave is efficiently absorbed by the plasma, and as a result, high density of a plasma in a wide range beyond the skin depth of the plasma is generated.

Meanwhile, at a timing (time T1) at which the first plasma processing process is switched to the second plasma processing process, the control device 11 controls the microwave output device 16 to switch the frequency of the microwave to the second frequency F2 that does not belong to the target frequency band. As a result, in the period in which the second plasma processing process is performed, the dielectric constant in the processing space S is negative, the magnetic permeability is positive, and the microwave cannot propagate in the processing space S. As a result, the plasma is present in a thickness that is the skin depth, the power of the microwave is not efficiently absorbed by the plasma, and high density of a plasma in a wide range is hindered.

Then, at a timing (time T2) at which the second plasma processing process is switched to the third plasma processing process, the control device 11 controls the microwave output device 16 to switch the frequency of the microwave to the first frequency F1 that belongs to the target frequency band again. As a result, in the period in which the third plasma processing process is performed, the dielectric constant and the magnetic permeability in the processing space S can both be made negative by the resonance between the microwave and the resonators 101, and the microwave can be propagated in the processing space S. As a result, in the processing space S in the processing container 12, since the plasma is present in a wide range beyond the skin depth, the power of the microwave is efficiently absorbed by the plasma, and as a result, high density of a plasma in a wide range beyond the skin depth of the plasma is generated.

In this way, by performing switching the frequency of the microwave between the first frequency that belongs to the target frequency band and the second frequency that does not belong to the target frequency band, the electron density of the plasma can be controlled to an electron density suitable for each plasma processing process when plasma processing processes are successively performed.

### Modification 2 of Plasma Control Processing

FIG. 19 is a view illustrating an example of a timing chart of plasma control processing according to Modification 2 of the first embodiment. In Modification 2, the control device 11 controls the microwave output device 16 to switch the frequency of the microwave between the first frequency that belongs to the target frequency band and the second frequency that does not belong to the target frequency band in the processing period of one plasma processing process performed by the plasma processing apparatus 1. For example, the plasma processing apparatus 1 successively executes a first plasma processing process, a second plasma processing process, and a third plasma processing process.

As illustrated in FIG. 19, for example, in the processing period (the period until the time T1) of the first plasma processing process, the control device 11 intermittently switches the frequency of the microwave between the first frequency F1 that belongs to the target frequency band and the second frequency F2 that does not belong to the target frequency band. The control device 11 may intermittently switch the frequency of the microwave in the processing period (the period from the time T1 to the time T2) of the second plasma processing process or in the processing period (the period from the time T2) of the third plasma processing process.

In this way, by intermittently switching the frequency of the microwave between the first frequency that belongs to the target frequency band and the second frequency that does not belong to the target frequency band, the electron density of the plasma can be intermittently switched in the processing period of one plasma processing process.

### Second Embodiment

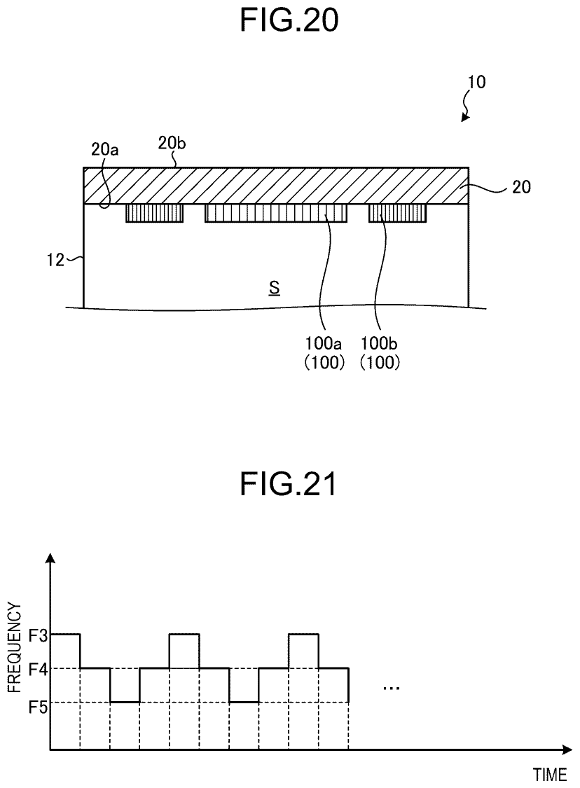

FIG. 20 is a schematic cross-sectional view illustrating an example of the apparatus main body 10 of the plasma processing apparatus 1 according to the second embodiment. The apparatus main body 10 according to the first embodiment includes the one resonator array structure 100 positioned in the processing container 12. In contrast, the apparatus main body 10 according to the second embodiment includes the resonator array structures 100 positioned in the processing container 12. Specifically, the apparatus main body 10 includes a first resonator array structure 100a and a second resonator array structure 100b.

Similar to the resonator array structure 100 illustrated in FIGS. 1 and 2, the first resonator array structure 100a and the second resonator array structure 100b are formed by arranging the resonators 101 in a lattice shape. The second resonator array structure 100b is different from the first resonator array structure 100a in resonance frequencies of the resonators 101. Therefore, the second resonator array structure 100b is different from the first resonator array structure 100a in the target frequency band in which the microwave and the resonators 101 resonate. That is, the first target frequency band corresponding to the first resonator array structure 100a is set to a frequency band higher than the resonance frequencies of the resonators 101 of the first resonator array structure 100a. In contrast, the second target frequency band corresponding to the second resonator array structure 100b is set to another frequency band higher than the resonance frequencies of the resonators 101 of the second resonator array structure 100b.

Further, each of the first resonator array structure 100a and the second resonator array structure 100b is disposed along the lower surface 20a of the dielectric window 20. For example, the first resonator array structure 100a is disposed on the central region of the lower surface 20a of the dielectric window 20, and the second resonator array structure 100b is annularly disposed on the outer peripheral region surrounding the central region of the lower surface 20a of the dielectric window 20.

FIG. 21 is a view illustrating an example of a timing chart of plasma control processing according to the second embodiment. As illustrated in FIG. 21, the control device 11 according to the second embodiment controls the microwave output device 16 to switch the frequency of the microwave between a third frequency F3, a fourth frequency F4, and a fifth frequency F5. Here, the third frequency F3 is a frequency that belongs to the first target frequency band corresponding to the first resonator array structure 100a, and the fourth frequency F4 is a frequency that belongs to the second target frequency band corresponding to the second resonator array structure 100b. Further, the fifth frequency F5 is a frequency that does not belong to either the first target frequency band or the second target frequency band.

In this way, by using the resonator array structures and switching the frequency of the microwave between the third and fourth frequencies that belong to the respective target frequency bands corresponding to the respective resonator array structures and the fifth frequency that does not belong to the target frequency band, the distribution of the electron density of the plasma can be finely controlled. For example, when the frequency of the microwave is set to the third frequency that belongs to the first target frequency band corresponding to the first resonator array structure 100a positioned on the central region of the lower surface 20a of the dielectric window 20, a high-density plasma can be generated only immediately below the central region of the lower surface 20a. Meanwhile, when the frequency of the microwave is switched to the fourth frequency that belongs to the second target frequency band corresponding to the second resonator array structure 100b positioned on the outer peripheral region of the lower surface 20a of the dielectric window 20, a high-density plasma can be generated only immediately below the outer peripheral region of the lower surface 20a.

### Third Embodiment

In the first embodiment, by controlling the frequency of the microwave to a frequency that belongs to the target frequency band, the generation of a high-density plasma in a wide range beyond the skin depth of the plasma is realized. In contrast, in the third embodiment, the resonance frequencies and the target frequency bands of the resonators 101 are controlled such that the frequency of the microwave belongs to the corresponding target frequency band. The configuration of the plasma processing apparatus 1 according to the third embodiment is the same as the configuration of the plasma processing apparatus 1 according to the first embodiment, and thus descriptions thereof will be omitted.

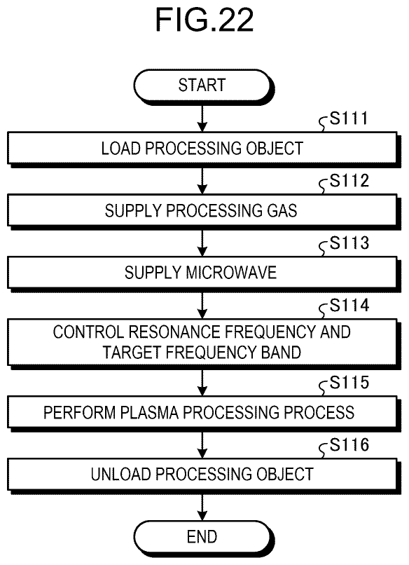

FIG. 22 is a flowchart illustrating an example of a processing flow of plasma control processing according to a third embodiment. The plasma control processing illustrated in FIG. 22 is realized by controlling each portion of the apparatus main body 10 by the control device 11. Each processing in steps S111 to S113, S115, and S116 in FIG. 22 is similar to each processing in the steps S101 to S103, S105, and S106 in FIG. 16, and thus descriptions thereof will be omitted.

When the microwave is supplied from the antenna 18 to the processing space S in the processing container 12 (step S113), a plasma of a processing gas is generated in the processing container 12. At this time, the electron density of the plasma reaches the cutoff density. When the electron density of the plasma reaches the cutoff density, the microwave cannot propagate in the processing space S in the processing container 12.

Therefore, the control device 11 controls a mechanical or chemical adjusting mechanism (not illustrated) provided in the resonators 101 to adjust a parameter that can change the resonance frequencies of the resonators 101. By adjusting the parameter that can change the resonance frequencies of the resonators 101, the control device 11 can control the resonance frequencies and the target frequency bands of the resonators 101 such that the frequency of the microwave belongs to the corresponding target frequency band (step S114). As a result, by generating the resonance between the microwave and the resonators 101, both the dielectric constant and the magnetic permeability of the plasma in the processing space S can be made negative, and as can be understood from Equation (1) above, the microwave can be propagated in the processing space S. As a result, in the processing space S in the processing container 12, since the plasma is present in a wide range beyond the skin depth, the power of the microwave is efficiently absorbed by the plasma, and as a result, high density of a plasma in a wide range beyond the skin depth of the plasma is generated.

The parameter that can change the resonance frequencies of the resonators 101 is, for example, a parameter that defines the shape of each of the first resonator 101A, the second resonator 101B, and the third resonator 101C illustrated in FIGS. 3 to 5. For example, a case where the resonators 101 includes the third resonator 101C (see FIGS. 5 and 6) is assumed. In this case, the parameter that can change the resonance frequencies of the resonators 101 is, for example, at least one of the thickness, the inner diameter, and the outer diameter of the ring member 111C. Further, the parameter that can change the resonance frequencies of the resonators 101 may be, for example, at least one of the thickness and the dielectric constant of the dielectric plate 112C. Further, the parameter that can change the resonance frequencies of the resonators 101 may be the stacked number N (N>2) of the ring members 111C in the third resonator 101C. Further, the above parameters may be combined as appropriate.

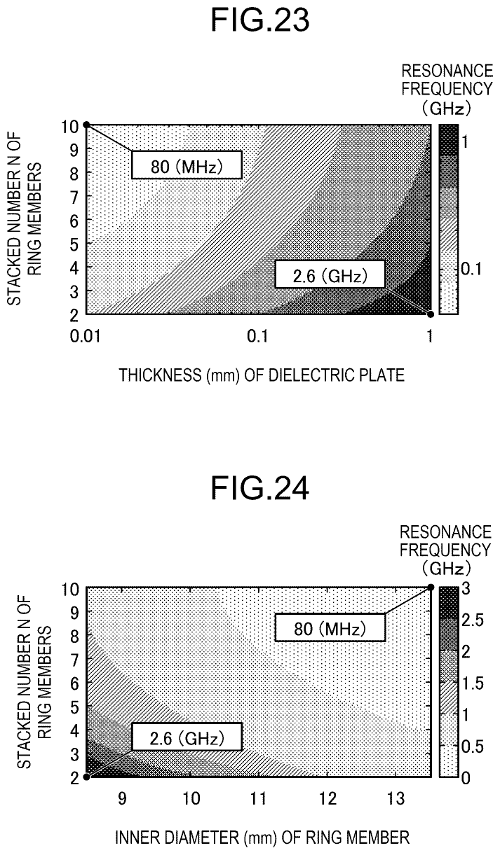

FIG. 23 is a view illustrating an example of a relationship between the resonance frequencies of the resonators 101, the stacked number N of the ring members 111C, and the thickness of the dielectric plate 112C. FIG. 24 is a view illustrating an example of a relationship between the resonance frequencies of the resonators 101, the stacked number N of the ring members 111C, and the inner diameter of the ring member 111C. As illustrated in FIGS. 23 and 24, by adjusting at least one of the stacked number N of the ring members 111C, the thickness of the dielectric plate 112C, and the inner diameter of the ring member 111C, the resonance frequencies of the resonators 101 can be controlled within the range of 80 MHz to 2.6 GHz.

In this way, by controlling the resonance frequencies and the target frequency bands of the resonators 101 such that the frequency of the microwave belongs to the target frequency band, the propagation of the microwave is present in a wide range beyond the skin depth of the plasma, so that the power of the microwave is efficiently absorbed by the plasma, and as a result, a high-density plasma in a wide range beyond the skin depth of the plasma can be generated.

### Other Modifications

In the embodiment described above, a case where the resonator array structure 100 is disposed along the lower surface 20a of the dielectric window 20 or disposed to be spaced apart from the lower surface 20a of the dielectric window 20 has been described as an example. Without being limited to this configuration, the resonator array structure 100 may be disposed along the upper surface of the electrostatic chuck 14c provided with the upper surface to face the processing space S, or may be disposed to be spaced apart from the upper surface of the electrostatic chuck 14c. Further, the resonator array structure 100 may be disposed along the inner wall surface of the side wall 12a of the processing container 12, or may be disposed to be spaced apart from the inner wall surface of the side wall 12a of the processing container 12. In short, the resonator array structure 100 may be disposed along one surface (first surface) of a member provided with the first surface to face the processing space S, or may be disposed to be spaced apart from the first surface of the member.

Further, in the embodiment described above, the output unit of the microwave output device 16 may be connected to the base 14a that is a radio-frequency electrode. In this case, the base 14a supplies the microwave that is output from the microwave output device 16 to the processing space S via the electrostatic chuck 14c. Further, in this configuration, the resonator array structure 100 may be embedded in the electrostatic chuck 14c.

Further, in the embodiment described above, a case where the resonator array structure 100 is formed by arranging the resonators 101 in a lattice shape, which can resonate with a magnetic field component of the microwave and whose size is smaller than a wavelength of the microwave, has been described as an example. Without being limited to this configuration, the resonators 101 may be arranged in any arrangement. For example, the resonators 101 may be arranged at predetermined intervals along one direction.

Further, in the embodiment described above, a case where the microwave output from the microwave output device 16 is propagated to the dielectric window 20 through the waveguide 21, the mode converter 27, the coaxial waveguide 28, and the antenna 18 has been described as an example. Without being limited to this configuration, the microwave may be directly propagated to the dielectric window 20 by the waveguide 21 without passing through the mode converter 27 and the coaxial waveguide 28. As a result, the waveguide 21 functions as an electromagnetic wave supply that supplies the microwave to the processing space S via the dielectric window 20. In this case, the mode converter 27, the coaxial waveguide 28, the slot plate 30, and the dielectric plate 32 can be omitted. In this way, by propagating the microwaves directly to the dielectric window 20 by the waveguide 21, the plasma can be generated immediately below the resonator array structure 100 without generating the plasma immediately below the dielectric window 20.

### Effects of Embodiments

A plasma processing apparatus (for example, the plasma processing apparatus 1) according to the embodiment described above includes a processing container (for example, the processing container 12), an electromagnetic wave generator (for example, the microwave output device 16), and a resonator array structure (for example, the resonator array structure 100). The processing container provides a processing space (for example, the processing space S). The electromagnetic wave generator generates an electromagnetic wave (for example, microwaves) for plasma excitation that is supplied to the processing space. The resonator array structure is formed by arranging resonators (for example, the resonators 101) configured to resonate with a magnetic field component of the electromagnetic wave and whose size is smaller than a wavelength of the electromagnetic wave, and is positioned in the processing container. Therefore, according to the embodiment, high density of a plasma in a wide range can be achieved.

Further, the resonator array structure may be disposed along a first surface of a member provided with the first surface to face the processing space S, or may be disposed to be spaced apart from the first surface of the member. Therefore, according to the embodiment, high density of a plasma in a wide range can be realized by using the resonator array structure positioned at any position in the processing container.

Further, the plasma processing apparatus may further include a dielectric (for example, the dielectric window 20) provided with a first surface (for example, the lower surface 20a) to face the processing space, and an electromagnetic wave supply (for example, the antenna 18) that supplies the electromagnetic wave to the processing space via the dielectric. The resonator array structure may be disposed along the first surface of the dielectric or may be disposed to be spaced apart from the first surface of the dielectric. Therefore, according to the embodiment, since the power of the electromagnetic wave can be efficiently absorbed into the plasma, high density of a plasma can be promoted in a wide range.

Further, a separation distance between the resonator array structure and the first surface may be smaller than a skin depth of a plasma on the first surface. Therefore, according to the embodiment, the power of the electromagnetic wave can be efficiently injected into the plasma.

Further, the plasma processing apparatus may further include a dielectric provided with a first surface to face the processing space, and an electromagnetic wave supply that supplies the electromagnetic wave to the processing space via the dielectric. The resonator array structure may be embedded in the dielectric. Therefore, according to the embodiment, since the power of the electromagnetic wave can be efficiently absorbed into the plasma, high density of a plasma can be promoted in a wide range.

Further, the resonator array structure may be spaced apart from the first surface and embedded in the dielectric. Further, the separation distance (for example, the separation distance D2) between the resonator array structure and the first surface may be 2/4 or less when the wavelength of the electromagnetic wave propagating through the dielectric is A. Therefore, according to the embodiment, since the electric field coupling between the resonator array structure and a plasma can be generated, the power of the electromagnetic wave can be efficiently injected into the plasma.

Further, the resonators may include at least one resonator of a first resonator (for example, the first resonator 101A), a second resonator (for example, the second resonator 101B), and a third resonator (for example, the third resonator 101C). The first resonator may have a structure in which two C-shaped ring members (for example, the ring members 111A), which are made of a conductor, in opposite directions from each other, and concentric with each other, are stacked on one surface of a dielectric plate (for example, the dielectric plate 112A). The second resonator may have a structure in which a dielectric plate (for example, the dielectric plate 112B) is interposed between both ends of a C-shaped ring member (for example, the ring member 111B) made of a conductor. The third resonator may have a structure in which N (N>2) C-shaped ring members (for example, the ring members 111C) are made of a conductor and a dielectric plate (for example, the dielectric plate 112C) is disposed between the ring members adjacently disposed in opposite directions from each other. Therefore, according to the embodiment, the electromagnetic wave and the resonators can be resonated by using the resonators having a simple structure.

Further, each of the resonators may configure a series resonance circuit constituted with a capacitor equivalent element and a coil equivalent element. Therefore, according to the embodiment, the electromagnetic wave and the resonators can be resonated by using the resonators having a simple structure.

Further, an insulating coating film formed on a surface of each of the resonators may be further provided. Therefore, according to the embodiment, the abnormal discharge in each of the resonators can be suppressed.

Further, the plasma processing apparatus may further include a controller (for example, the control device 11). The controller may control the electromagnetic wave generator or may control an adjusting mechanism that adjusts a parameter configured to change a resonance frequency of the resonators, to resonate the electromagnetic wave supplied to the processing space and the resonators in a target frequency band higher than the resonance frequency of the resonators when a plasma is generated in the processing space. Further, a bandwidth of the target frequency band may be 0.05 times or less the resonance frequency of the resonators. Therefore, according to the embodiment, high density of a plasma in a wide range can be achieved.

Further, the controller may control the electromagnetic wave generator to control a frequency of the electromagnetic wave supplied to the processing space to a frequency that belongs to the target frequency band. Therefore, according to the embodiment, high density of a plasma in a wide range can be achieved.

Further, the controller may control the electromagnetic wave generator to switch the frequency of the electromagnetic wave between a first frequency that belongs to the target frequency band and a second frequency that does not belong to the target frequency band, according to a timing for switching plasma processing processes successively performed by the plasma processing apparatus. Therefore, according to the embodiment, when the plasma processing processes are successively performed, the electron density of the plasma can be controlled to an electron density suitable for each plasma processing process.

Further, the controller may control the electromagnetic wave generator to switch the frequency of the electromagnetic wave between a first frequency that belongs to the target frequency band and a second frequency that does not belong to the target frequency band in a processing period of one plasma processing process performed by the plasma processing apparatus. Therefore, according to the embodiment, the electron density of the plasma can be intermittently switched in the processing period of one plasma processing process.

Further, the plasma processing apparatus may include resonator array structures. The resonator array structures may also include a first resonator array structure (for example, the first resonator array structure 100a) and a second resonator array structure (for example, the second resonator array structure 100b) having a different resonance frequency of the resonators from the first resonator array structure. In this case, the controller may control the electromagnetic wave generator to switch the frequency of the electromagnetic wave between a third frequency that belongs to a first target frequency band corresponding to the first resonator array structure, a fourth frequency that belongs to a second target frequency band corresponding to the second resonator array structure, and a fifth frequency that does not belong to the first target frequency band and the second target frequency band. Therefore, according to the embodiment, the distribution of the electron density of the plasma can be finely controlled.

Further, the electromagnetic wave may be an electromagnetic wave (for example, a broadband microwave) that includes frequency components that belong to a predetermined frequency bandwidth. In this case, the controller may control the electromagnetic wave generator to control a frequency of the frequency components included in the electromagnetic wave supplied to the processing space to the target frequency band. Therefore, according to the embodiment, although the plasma is excited by using a broadband microwave, high density of a plasma in a wide range can be realized.

Further, the controller may control the electromagnetic wave generator and adjust the parameter to control the resonance frequency of the resonators and the target frequency band such that a frequency of the electromagnetic wave belongs to the target frequency band.

Therefore, according to the embodiment, high density of a plasma in a wide range can be achieved.

According to the present disclosure, high density of a plasma in a wide range can be achieved.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

With respect to the above-described embodiments, the following appendixes will be further disclosed.

### (Appendix 1)

A plasma processing apparatus including:

a processing container that provides a processing space;

an electromagnetic wave generator that generates an electromagnetic wave for plasma excitation that is supplied to the processing space; and

a resonator array structure that is formed by arranging resonators configured to resonate with a magnetic field component of the electromagnetic wave, each of the resonators having a size smaller than a wavelength of the electromagnetic wave, and is positioned in the processing container.

### (Appendix 2)

The plasma processing apparatus according to Appendix 1, in which the resonator array structure is disposed along a first surface of a member provided with the first surface facing the processing space, or is disposed to be spaced apart from the first surface of the member.

### (Appendix 3)

The plasma processing apparatus according to Appendix 2, further including:
a dielectric provided with a first surface facing the processing space; and

an electromagnetic wave supply that supplies the electromagnetic wave to the processing space via the dielectric, in which

the resonator array structure is disposed along the first surface of the dielectric or is disposed to be spaced apart from the first surface of the dielectric.

### (Appendix 4)

The plasma processing apparatus according to Appendix 3, in which

a separation distance between the resonator array structure and the first surface is smaller than a skin depth of a plasma on the first surface.

### (Appendix 5)

The plasma processing apparatus according to Appendix 1, further including:

a dielectric provided with a first surface facing the processing space; and

an electromagnetic wave supply that supplies the electromagnetic wave to the processing space via the dielectric, in which

the resonator array structure is embedded in the dielectric.

### (Appendix 6)

The plasma processing apparatus according to Appendix 5, in which

the resonator array structure is spaced apart from the first surface and embedded in the dielectric, and

a separation distance between the resonator array structure and the first surface is λ/4 or less when the wavelength of the electromagnetic wave propagating through the dielectric is λ.

### (Appendix 7)

The plasma processing apparatus according to any one of Appendixes 1 to 6, in which

the resonators include at least one resonator of a first resonator, a second resonator, and a third resonator,

the first resonator has a structure in which two C-shaped ring members, which are made of a conductor, in opposite directions from each other, and concentric with each other, are stacked on one surface of a dielectric plate,

the second resonator has a structure in which a dielectric plate is interposed between both ends of a C-shaped ring member made of a conductor, and

the third resonator has a structure in which a dielectric plate is disposed between N (N≥2) C-shaped ring members, which are made of a conductor and are adjacently disposed in opposite directions from each other.

### (Appendix 8)

The plasma processing apparatus according to Appendix 7, in which

each of the resonators configures a series resonance circuit constituted with a capacitor equivalent element and a coil equivalent element.

### (Appendix 9)

The plasma processing apparatus according to any one of Appendices 1 to 8, further including an insulating coating film formed on a surface of each of the resonators.

### (Appendix 10)

The plasma processing apparatus according to any one of Appendices 1 to 9, further including a controller that controls the electromagnetic wave generator or controls an adjusting mechanism that adjusts a parameter configured to change a resonance frequency of the resonators, to resonate the electromagnetic wave supplied to the processing space and the resonators in a target frequency band higher than the resonance frequency of the resonators when a plasma is generated in the processing space.

### (Appendix 11)

The plasma processing apparatus according to Appendix 10, in which

the controller controls the electromagnetic wave generator to control a frequency of the electromagnetic wave supplied to the processing space to a frequency that belongs to the target frequency band.

### (Appendix 12)

The plasma processing apparatus according to Appendix 11, in which

the controller controls the electromagnetic wave generator to switch the frequency of the electromagnetic wave between a first frequency that belongs to the target frequency band and a second frequency that does not belong to the target frequency band, according to a timing for switching plasma processing processes successively performed by the plasma processing apparatus.

### (Appendix 13)

The plasma processing apparatus according to Appendix 11, in which

the controller controls the electromagnetic wave generator to switch the frequency of the electromagnetic wave between a first frequency that belongs to the target frequency band and a second frequency that does not belong to the target frequency band in a processing period of one plasma processing process performed by the plasma processing apparatus.

### (Appendix 14)

The plasma processing apparatus according to Appendix 11, in which

resonator array structures are provided,

the resonator array structures include

a first resonator array structure and a second resonator array structure having a different resonance frequency of the resonators from the first resonator array structure, and

the controller controls the electromagnetic wave generator to switch the frequency of the electromagnetic wave between a third frequency that belongs to a first target frequency band corresponding to the first resonator array structure, a fourth frequency that belongs to a second target frequency band corresponding to the second resonator array structure, and a fifth frequency that does not belong to the first target frequency band and the second target frequency band.

### (Appendix 15)

The plasma processing apparatus according to Appendix 11, in which

the electromagnetic wave is an electromagnetic wave that includes frequency components that belong to a predetermined frequency bandwidth, and

the controller controls the electromagnetic wave generator to control a frequency of the frequency components included in the electromagnetic wave supplied to the processing space to the target frequency band.

### (Appendix 16)

The plasma processing apparatus according to Appendix 10, in which

the controller controls the adjusting mechanism and adjusts the parameter to control the resonance frequency of the resonators and the target frequency band such that a frequency of the electromagnetic wave belongs to the target frequency band.

### (Appendix 17)

The plasma processing apparatus according to any one of Appendices 10 to 16, in which

a bandwidth of the target frequency band is 0.05 times or less the resonance frequency of the resonators.

### (Appendix 18)

A plasma control method of a plasma processing apparatus including

a processing container that provides a processing space,

an electromagnetic wave generator that generates an electromagnetic wave for plasma excitation that is supplied to the processing space, and

a resonator array structure that is formed by arranging resonators configured to resonate with a magnetic field component of the electromagnetic wave, each of the resonators having a size smaller than a wavelength of the electromagnetic wave, and is positioned in the processing container, the plasma control method including:

controlling the electromagnetic wave generator or controlling an adjusting mechanism that adjusts a parameter configured to change a resonance frequency of the resonators, to resonate the electromagnetic wave supplied to the processing space and the resonators in a target frequency band higher than the resonance frequency of the resonators when a plasma is generated in the processing space.

What is claimed is:

1. A plasma processing apparatus comprising:
a processing container that provides a processing space;
an electromagnetic wave generator that generates an electromagnetic wave for plasma excitation that is supplied to the processing space; and
a resonator array structure that is formed by arranging resonators configured to resonate with a magnetic field component of the electromagnetic wave, each of the resonators having a size smaller than a wavelength of the electromagnetic wave, and is positioned in the processing container.

2. The plasma processing apparatus according to claim 1, wherein
the resonator array structure is disposed along a first surface of a member provided with the first surface facing the processing space, or is disposed to be spaced apart from the first surface of the member.

3. The plasma processing apparatus according to claim 2, further comprising:
a dielectric provided with a first surface facing the processing space; and
an electromagnetic wave supply that supplies the electromagnetic wave to the processing space via the dielectric, wherein
the resonator array structure is disposed along the first surface of the dielectric or is disposed to be spaced apart from the first surface of the dielectric.

4. The plasma processing apparatus according to claim 3, wherein
a separation distance between the resonator array structure and the first surface is smaller than a skin depth of a plasma on the first surface.

5. The plasma processing apparatus according to claim 1, further comprising:
a dielectric provided with a first surface facing the processing space; and
an electromagnetic wave supply that supplies the electromagnetic wave to the processing space via the dielectric, wherein
the resonator array structure is embedded in the dielectric.

6. The plasma processing apparatus according to claim 5, wherein
the resonator array structure is spaced apart from the first surface and embedded in the dielectric, and
a separation distance between the resonator array structure and the first surface is λ/4 or less when the wavelength of the electromagnetic wave propagating through the dielectric is λ.

7. The plasma processing apparatus according to claim 1, wherein
the resonators include at least one resonator of a first resonator, a second resonator, and a third resonator,
the first resonator has a structure in which two C-shaped ring members, which are made of a conductor, in opposite directions from each other, and concentric with each other, are stacked on one surface of a dielectric plate,
the second resonator has a structure in which a dielectric plate is interposed between both ends of a C-shaped ring member made of a conductor, and
the third resonator has a structure in which a dielectric plate is disposed between N (N≥2) C-shaped ring members, which are made of a conductor and are adjacently disposed in opposite directions from each other.

8. The plasma processing apparatus according to claim 7, wherein
each of the resonators configures a series resonance circuit constituted with a capacitor equivalent element and a coil equivalent element.

9. The plasma processing apparatus according to claim 1, further comprising an insulating coating film formed on a surface of each of the resonators.

10. The plasma processing apparatus according to claim 1, further comprising a controller that controls the electromagnetic wave generator or controls an adjusting mechanism that adjusts a parameter configured to change a resonance frequency of the resonators, to resonate the electromagnetic wave supplied to the processing space and the resonators in a target frequency band higher than the resonance frequency of the resonators when a plasma is generated in the processing space.

11. The plasma processing apparatus according to claim 10, wherein
the controller controls the electromagnetic wave generator to control a frequency of the electromagnetic wave supplied to the processing space to a frequency that belongs to the target frequency band.

12. The plasma processing apparatus according to claim 11, wherein
the controller controls the electromagnetic wave generator to switch the frequency of the electromagnetic wave between a first frequency that belongs to the target frequency band and a second frequency that does not belong to the target frequency band, according to a timing for switching plasma processing processes successively performed by the plasma processing apparatus.

13. The plasma processing apparatus according to claim 11, wherein
the controller controls the electromagnetic wave generator to switch the frequency of the electromagnetic wave between a first frequency that belongs to the target frequency band and a second frequency that does not belong to the target frequency band in a processing period of one plasma processing process performed by the plasma processing apparatus.

14. The plasma processing apparatus according to claim 11, wherein
resonator array structures are provided,
the resonator array structures include
a first resonator array structure and a second resonator array structure having a different resonance frequency of the resonators from the first resonator array structure, and
the controller controls the electromagnetic wave generator to switch the frequency of the electromagnetic wave between a third frequency that belongs to a first target frequency band corresponding to the first resonator array structure, a fourth frequency that belongs to a second target frequency band corresponding to the second resonator array structure, and a fifth frequency that does not belong to the first target frequency band and the second target frequency band.

15. The plasma processing apparatus according to claim 11, wherein
the electromagnetic wave is an electromagnetic wave that includes frequency components that belong to a predetermined frequency bandwidth, and
the controller controls the electromagnetic wave generator to control a frequency of the frequency components included in the electromagnetic wave supplied to the processing space to the target frequency band.

16. The plasma processing apparatus according to claim 10, wherein
the controller controls the adjusting mechanism and adjusts the parameter to control the resonance frequency of the resonators and the target frequency band such that a frequency of the electromagnetic wave belongs to the target frequency band.

17. The plasma processing apparatus according to claim 10, wherein
a bandwidth of the target frequency band is 0.05 times or less the resonance frequency of the resonators.

18. A plasma control method of a plasma processing apparatus including
a processing container that provides a processing space,
an electromagnetic wave generator that generates an electromagnetic wave for plasma excitation that is supplied to the processing space, and
a resonator array structure that is formed by arranging resonators configured to resonate with a magnetic field component of the electromagnetic wave, each of the resonators having a size smaller than a wavelength of the electromagnetic wave, and is positioned in the processing container, the plasma control method comprising:
controlling the electromagnetic wave generator or controlling an adjusting mechanism that adjusts a parameter configured to change a resonance frequency of the resonators, to resonate the electromagnetic wave supplied to the processing space and the resonators in a target frequency band higher than the resonance frequency of the resonators when a plasma is generated in the processing space.
